(19) United States
(12) Patent Application Publication
(10) Pub. No.: US 2026/0312362 A1
(43) Pub. Date: Oct. 8, 2026

(54) LATERAL GROUNDING STRUCTURE FOR FREQUENCY NOISE REDUCTION IN LASER WAVEGUIDES

(71) Applicant: Lumentum Operations LLC, San Jose, CA (US)

(72) Inventors: Michael C. LARSON, Oakland, CA (US); Yahong QIAN, Northampton (GB); Duanhua KONG, Milpitas, CA (US)

(21) Appl. No.: 19/252,498

(22) Filed: Jun. 27, 2025

Related U.S. Application Data
(60) Provisional application No. 63/782,119, filed on Apr. 2, 2025.

(51) Int. Cl. H01S 5/026; H01S 5/0625; H01S 5/227; H01S 5/323

(52) U.S. Cl. CPC H01S 5/0261; H01S 5/06256; H01S 5/2275; H01S 5/323

(57) ABSTRACT

A waveguide structure includes a waveguide ridge that extends outward from an upper cladding layer in a vertical direction. The waveguide ridge is formed by a not-intentionally-doped spacer layer, the upper cladding layer, and a contact layer arranged in a layer stack. The undoped spacer layer is arranged on a waveguide core layer and extends from the waveguide core layer in the vertical direction to form a protrusion that forms a partial bottom portion of the waveguide ridge. The upper cladding layer laterally surrounds and extends over an upper surface of the undoped spacer layer to form peripheral portions and a middle portion of the waveguide ridge. The contact layer is arranged on the upper cladding layer to form an upper portion of the waveguide ridge. A ground ohmic contact is arranged on the primary waveguide ridge, the ground ohmic contact being in contact with the contact layer.

### CROSS-REFERENCE TO RELATED APPLICATION

This Patent Application claims priority to U.S. Provisional Patent Application No. 63/782,119, filed on Apr. 2, 2025, and entitled “LATERAL GROUNDING STRUCTURE FOR FREQUENCY NOISE REDUCTION.” The disclosure of the prior Application is considered part of and is incorporated by reference into this Patent Application.

### TECHNICAL FIELD

The present disclosure relates generally to laser waveguides.

### BACKGROUND

A narrow linewidth, widely-tunable semiconductor laser is a specialized type of laser that emits laser light with a very small spectral width (narrow linewidth) and can be tuned across a broad range of wavelengths (widely tunable). These characteristics make the narrow linewidth, widely-tunable semiconductor laser ideal for applications that require high coherence and precise wavelength control. With a narrow linewidth, the narrow linewidth, widely-tunable semiconductor laser emits light with a very small frequency variation, typically in the kilohertz (kHz) or sub-kHz range, achieving high coherence. This high coherence is useful for spectroscopy, coherent optical communication, and sensing applications. With wide tunability, an output wavelength of the narrow linewidth, widely-tunable semiconductor laser can be tuned over a broad spectral range, often tens of nanometers or more. Wavelength tunning may be achieved through mechanisms such as thermal tuning, current injection, or external cavity designs. The narrow linewidth, widely-tunable semiconductor laser may be a semiconductor-based laser that uses one or more semiconductor gain materials for generating laser light.

### SUMMARY

In some implementations, a waveguide structure includes a substrate; a lower cladding layer arranged on the substrate; a waveguide core layer arranged on the lower cladding layer, the waveguide core layer configured to generate, guide, and amplify laser light; a back distributed Bragg reflector (DBR) arranged in the waveguide core layer; a front DBR arranged in the waveguide core layer, wherein the back DBR and the front DBR define a laser cavity of the waveguide core layer; one or more active regions arranged in the waveguide core layer for light generation and amplification; an upper cladding layer arranged on the waveguide core layer, wherein the lower cladding layer, the waveguide core layer, and the upper cladding layer form a waveguide; a thermally-controllable heater arranged on the upper cladding layer, the thermally-controllable heater configured to thermally tune a thermally-controllable section of the waveguide core layer; a primary waveguide ridge that extends outward from the upper cladding layer in a vertical direction, wherein the primary waveguide ridge is formed by a not-intentionally-doped spacer layer, the upper cladding layer, and a contact layer arranged in a layer stack, wherein the undoped spacer layer is arranged on the waveguide core layer and extends from the waveguide core layer in the vertical direction to form a protrusion that forms a partial bottom portion of the primary waveguide ridge, wherein the upper cladding layer laterally surrounds and extends over an upper surface of the undoped spacer layer to form peripheral portions and a middle portion of the primary waveguide ridge, and the contact layer is arranged on the upper cladding layer to form an upper portion of the primary waveguide ridge; and a ground ohmic contact arranged on the primary waveguide ridge, the ground ohmic contact being in contact with the contact layer.

In some implementations, a waveguide structure includes a substrate; a lower cladding layer arranged on the substrate; a waveguide core layer arranged on the lower cladding layer, the waveguide core layer configured to generate, guide and amplify laser light; a back DBR arranged in the waveguide core layer; a front DBR arranged in the waveguide core layer, wherein the back DBR and the front DBR define a laser cavity of the waveguide core layer; one or more active regions arranged in the waveguide core layer for light generation and amplification; an upper cladding layer arranged on the waveguide core layer, wherein the lower cladding layer, the waveguide core layer, and the upper cladding layer form a waveguide; a thermally-controllable heater arranged on the upper cladding layer, the thermally-controllable heater configured to thermally tune a thermally-controllable section of the waveguide core layer; a primary waveguide ridge that extends outward from the waveguide core layer in a vertical direction, wherein the primary waveguide ridge is formed by a not-intentionally-doped spacer layer, and a doped layer arranged on the undoped spacer layer, wherein the undoped spacer layer is arranged on the waveguide core layer and extends from the waveguide core layer in the vertical direction to form a protrusion that forms a bottom portion of the primary waveguide ridge, and wherein the doped layer is arranged on the undoped spacer layer to form an upper portion of the primary waveguide ridge; a first secondary ridge laterally displaced from the primary waveguide ridge in a first lateral direction, wherein the first secondary ridge is formed by a first protrusion of the upper cladding layer and a first contact layer arranged on the first protrusion of the upper cladding layer; and a first ground ohmic contact arranged on the first secondary ridge, the first ground ohmic contact being in contact with the first contact layer.

In some implementations, a method of manufacturing a monolithically-integrated narrow-linewidth tunable semiconductor laser device includes providing an initial layer stack, comprising: a lower cladding layer, the lower cladding layer having a doping of a first conductivity type, a waveguide core layer arranged on the lower cladding layer, a separation layer arranged on the waveguide core layer, the separation layer being undoped, and a not-intentionally-doped setback layer arranged on the separation layer; etching the undoped setback layer to form a not-intentionally-doped mesa structure; forming an upper cladding layer, the upper cladding layer having a doping of a second conductivity type, wherein forming the upper cladding layer comprises: doping the separation layer with dopants of the second conductivity type, where a section of the separation layer underneath the undoped mesa structure remains undoped; and growing an additional doped layer over the separation layer and over the undoped mesa structure such that the additional doped layer covers peripheral sides and an upper surface of the undoped mesa structure; forming a contact layer on the additional doped layer, the contact layer having a doping of a second conductivity type; etching the contact layer and the additional doped layer to form a primary waveguide ridge and a plurality of secondary ridges, wherein the primary waveguide ridge includes the undoped mesa structure, a portion of the additional doped layer, and a portion of the contact layer, and wherein the portion of the additional doped layer covers the peripheral sides and the upper surface of the undoped mesa structure; and forming a ground ohmic contact on the portion of the contact layer.

In some implementations, a waveguide structure includes a substrate; a lower cladding layer arranged on the substrate; a waveguide core layer; an upper cladding layer arranged on the waveguide core layer, wherein the lower cladding layer, the waveguide core layer, and the upper cladding layer form a waveguide; a thermally-controllable heater arranged on the upper cladding layer, the thermally-controllable heater configured to thermally tune a thermally-controllable section of the waveguide core layer; a primary waveguide ridge that extends outward from the upper cladding layer in a vertical direction, wherein the primary waveguide ridge is formed by a not-intentionally-doped spacer layer, the upper cladding layer, and a contact layer arranged in a layer stack, wherein the undoped spacer layer is arranged on the waveguide core layer and extends from the waveguide core layer in the vertical direction to form a protrusion that forms a partial bottom portion of the primary waveguide ridge, wherein the upper cladding layer laterally surrounds and extends over an upper surface of the undoped spacer layer to form peripheral portions and a middle portion of the primary waveguide ridge, and the contact layer is arranged on the upper cladding layer to form an upper portion of the primary waveguide ridge; and a ground ohmic contact arranged on the primary waveguide ridge, the ground ohmic contact being in contact with the contact layer.

### BRIEF DESCRIPTION OF THE DRAWINGS

FIG. 1 shows a length-wise cross-section of a waveguide structure, with thermal tuning, associated with a narrow linewidth, widely-tunable semiconductor laser device according to one or more implementations.

FIG. 2 shows a transverse cross-section of a waveguide structure according to one or more implementations.

FIG. 3 shows a cross-section of a waveguide structure according to one or more implementations.

FIGS. 4A-4D show a fabrication process to produce a ridge-top-ground waveguide structure according to one or more implementations.

### DETAILED DESCRIPTION

The following detailed description of example implementations refers to the accompanying drawings. The same reference numbers in different drawings may identify the same or similar elements.

A Vernier-tuned laser structure is a type of tunable semiconductor laser that uses a Vernier effect to achieve wide wavelength tuning. The Vernier-tuned laser structure may include two or more wavelength-selective elements. By tuning the two or more wavelength-selective elements together, a wavelength may be selected at which transmission peaks of the two or more wavelength-selective elements align, allowing for a large tuning range. The Vernier-tuned laser structure includes a thermally-tuned front mirror, a thermally-tuned back mirror, thermally-tuned phase sections, and passive waveguide sections connecting the phase sections. The front and back mirrors, together, provide supermode selection and enhanced longitudinal mode selection.

A semiconductor optical amplifier (SOA) is an optical amplifier based on semiconductor gain media. A quantum well is a thin, nanometer-scale layer of semiconductor material designed to confine electrons or holes in one dimension (perpendicular to the layer surface), while allowing them to move freely in the other two dimensions. A multiple quantum wells (MQW) structure consists of multiple quantum wells separated by thin barrier layers, typically made of a semiconductor material with a wider bandgap than the well material. MQWs are used as an active region in laser diodes, where optical gain is provided. The Vernier-tuned laser structure contains one or more amplifying sections situated between the front and back mirrors and this is referred to as the gain section.

Ideally, the Vernier-tuned laser structure would be transparent to a guided optical mode and tunable through a thermo-optic effect (e.g., through a local temperature-induced refractive index change from one or more electrically-isolated but thermally-connected resistive microheaters). In reality, waveguides are formed by semiconductor materials with electron and valence bands that are doped with impurities to form p-i-n diodes. A p-i-n diode enables electrical current injection into a laser active region to produce optical gain through stimulated emission, but the p-i-n diode is largely unnecessary for thermally tuned or passive waveguides. Moreover, carrier fluctuations (e.g., generation and recombination of electron-hole pairs) naturally arise in these nominally transparent semiconductor waveguides. Generation processes include thermal generation and nonlinear optical (2 photon) absorption. Recombination is through nonradiative (defect or trap assisted), radiative, or Auger recombination. The generation and recombination of carriers produces an unwanted refractive index fluctuation over time. These fluctuations in turn lead to excess frequency noise in a Fourier frequency range up to ~10-100 MHz (referred to as excess mid-band frequency noise), which is associated with a time constant of the recombination processes themselves. This excess noise is also additive to white (Gaussian) noise associated with an instantaneous laser linewidth. A laser with this excess noise, when used as a local oscillator in a coherent transmission system, will result in a degradation in signal recovery, which ultimately limits a transmission distance of the laser.

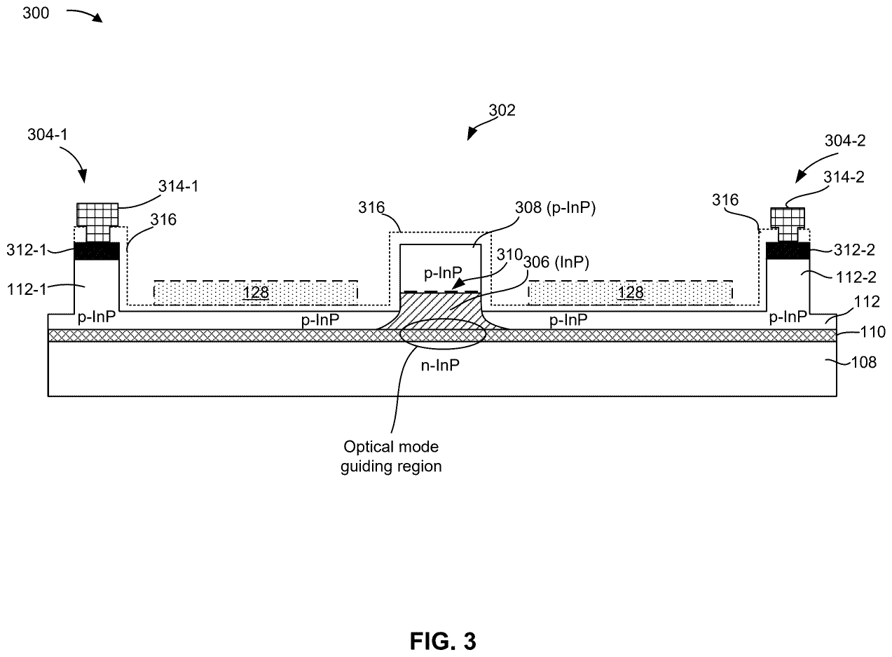

Carrier fluctuations can be reduced if quasi-Fermi level(s) in a semiconductor material (e.g., InGaAsP) that makes up tuning waveguide sections of the Vernier-tuned laser structure is held at a constant potential. The quasi-Fermi level(s) describe a chemical potential, or population statistics, for electrons and holes in a p-i-n diode, and these chemical potentials can be fixed by electrically connecting them to external voltage sources. For example, fixing the chemical potentials can be achieved by forming a metal electrode and ohmic contact to a p-doped upper cladding of a waveguide, and electrically connecting (grounding) the electrode to an n-doped lower cladding through a common n-doped substrate, as shown example 300 in FIG. 3. In this case, the fixed potential difference is zero volts. This prior approach—called a ridge-top-ground (RTG) because it places a contact vertically on an etched ridge waveguide—adds excessive optical absorption from free carrier absorption in the p-doped InP, inter-band absorption in the p+InGaAs contact layer, and absorption from the metal ohmic contacts. The excessive optical absorption, when combined with an intense optical propagating beam within a laser cavity, leads to optically-induced self-heating, which produces an unintended thermal gradient along a length of front and back mirrors of the Vernier-tuned laser structure. The unintended thermal gradient creates an unwanted chirping of the gratings forming each mirror, which degrades spectral filtering properties of the front and back mirrors, and in turn degrades a spectral purity of the laser light.

Some implementations provide a waveguide structure with improved frequency noise properties. The waveguide structure may be part of a narrow linewidth, widely-tunable semiconductor laser with improved frequency noise properties. The waveguide structure may include a Vernier-tuned laser structure for providing wavelength-tunable laser light having a narrow linewidth. The waveguide structure may be configured to mitigate carrier fluctuations in a thermally-tuned front mirror, a thermally-tuned back mirror, thermally-tuned phase sections, and passive waveguide sections in a manner that is compatible with the Vernier-tuned laser structure. Accordingly, techniques may be used to control carrier fluctuations in a way that minimizes an optical absorption in a waveguide. In some implementations, a monolithically-integrated narrow linewidth tunable semiconductor laser for coherent transmission at 800 Gbps and greater, with extended band tuning range (C++, L++), is provided. The C++ band and L++ band refer to extended wavelength ranges in optical fiber communication beyond the standard C-band (1530-1565 nm) and L-band (1565-1625 nm). For example, the C++ band includes a wavelength range of 1505-1530 nm in addition to the standard C-band, and the L++ band includes a wavelength range of 1625-1675 nm in addition to the standard L-band.

In some implementations, an undoped spacer layer (so-called doping setback layer or not-intentionally-doped spacer layer) that has been laterally patterned may be provided. Accordingly, p-doping in a periphery of a ridge waveguide facilitates electrical grounding while not contributing excessive optical loss. The undoped spacer keeps an evanescent optical field away from the absorbing layers. In addition, a lossy p+-InGaAs contact layer and a metal electrode are moved to so-called “secondary ridges” which run parallel to a “primary” (optically-active) ridge waveguide. A lateral conduction path between the secondary ridges and the primary ridge waveguide provides carrier fluctuation control.

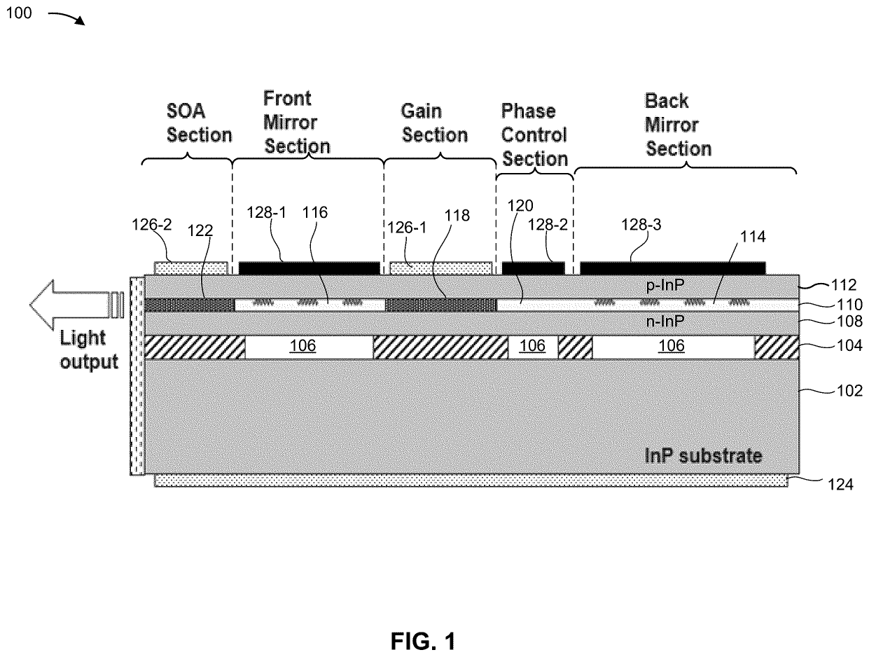

FIG. 1 shows a cross-section of a waveguide structure 100, with thermal tuning, associated with a narrow linewidth, widely-tunable semiconductor laser device. The cross-section may be taken along a length-wise dimension of the waveguide structure 100, parallel to an output direction of output laser light (e.g. parallel to a propagation direction).

The waveguide structure 100 may be a Vernier-tuned laser structure. Narrow linewidth, widely-tunable semiconductor laser structures of the waveguide structure 100 may be a monolithically-integrated for coherent transmission at 800 Gbps and greater, with extended band tuning range (C++, L++). In some examples, the waveguide structure 100 may be referred to as a ridge waveguide structure having one or more waveguide ridges (e.g., a primary waveguide ridge and secondary waveguide ridges).

The waveguide structure 100 may include a substrate 102 (e.g., an indium phosphide (InP) substrate); a sacrificial layer 104 arranged on the substrate 102 and defining thermal isolation sections 106 (e.g., air gaps), a lower cladding layer 108 arranged on the substrate 102 (e.g., arranged on the sacrificial layer 104), a waveguide core layer 110 arranged on the lower cladding layer 108, and an upper cladding layer 112 arranged on the waveguide core layer 110. The lower cladding layer 108, the waveguide core layer 110, and the upper cladding layer 112 form a waveguide. The waveguide core layer 110 is configured to generate, guide, and amplify laser light. In some examples, the lower cladding layer 108 may be an n-doped InP layer (e.g., an n-InP layer), the waveguide core layer 110 may be an InGaAsP layer, and the upper cladding layer 112 may be a p-doped InP layer (e.g., a p-InP layer). An n-type doping may be referred to as a first conductivity type, and a p-type doping may be referred to as a second conductivity type.

The waveguide structure 100 may further include a back distributed Bragg reflector (DBR) 114 arranged in the waveguide core layer 110, a front DBR 116 arranged in the waveguide core layer 110, and a first active region 118 arranged in the waveguide core layer 110 for light generation and amplification, a phase control section 120 arranged in the waveguide core layer 110, and a second active region 122 arranged in the waveguide core layer 110 for light amplification. The back DBR 114 and the front DBR 116 define a laser cavity of the waveguide core layer 110 in which the first active region 118 and the phase control section 120 are arranged. The first active region 118 includes an optical gain medium for generating and amplifying light based on a stimulated emission. Intracavity light is reflected back and forth inside the laser cavity between the back DBR 114 and the front DBR 116, and some intracavity light eventually exits the laser cavity as laser light. The phase control section 120 may be thermally-controlled (e.g., thermally-tuned) to adjust a round-trip phase of the intracavity light. The second active region 122 includes an optical gain medium for amplifying light, that exits the laser cavity, prior to the light being output from the waveguide structure 100. The second active region 122 may form an SOA, and thus, may be provided in an SOA section of the waveguide structure 100.

The waveguide structure 100 may further include a bottom electrode 124 and multiple top electrodes 126-1 and 126-2. The top electrodes 126-1, 126-2 may each be arranged over a corresponding active region to pump electrical current through its corresponding active region for inducing stimulated emission in the corresponding active region. Electrical current flows through from the top electrodes 126-1 and 126-2, through the corresponding active region, to the bottom electrode 124, or vice versa. Thus, the top electrode 126-1 may be arranged over the first active region 118, and the top electrode 126-2 may be arranged over the second active region 122.

The waveguide structure 100 may further include multiple thermally-controllable heaters (e.g., microheaters) over the non-active regions of the waveguide core layer 110. Thus, the multiple thermally-controllable heaters may be arranged on the upper cladding layer 112. The multiple thermally-controllable heaters may each thermally tune a corresponding thermally-controllable section of the waveguide core layer 110. The multiple thermally-controllable heaters may be controlled to apply a thermally-controlled amount of heat to their corresponding thermally-controllable sections. For example, the multiple thermally-controllable heaters may include a first thermally-controllable heater 128-1 arranged over the front DBR 116 for thermally-tuning the front DBR 116. In addition, the multiple thermally-controllable heaters may include a second thermally-controllable heater 128-2 arranged over the phase control section 120 for thermally-tuning the phase control section 120. In addition, the multiple thermally-controllable heaters may include a third thermally-controllable heater 128-3 arranged over the back DBR 114 for thermally-tuning the back DBR 114.

The back DBR 114 and the front DBR 116 function as wavelength-selective elements that can be thermally-tuned to adjust a wavelength of the laser light output from the laser cavity. Temperature affects a refractive index of semiconductor material due to a thermo-optic effect. Thermally-tuning the back DBR 114 and the front DBR 116 causes reflectivity peaks of the back DBR 114 and the front DBR 116 to shift based on the thermo-optic effect such that a wavelength at which the reflectivity peaks of the back DBR 114 and the front DBR 116 align changes. As a result, the wavelength of the laser light output from the laser cavity changes. This type of wavelength turning is referred to as “Vernier effect-based tuning.” Thus, the front DBR 116 and the back DBR 114 form a wavelength selective filter such that the laser light is generated within a narrow band of wavelengths. In addition, by using the thermo-optic effect to change the refractive index in the phase control section 120, the round-trip phase of the intracavity light may be adjusted, which fine tunes the wavelength which is resonant to the cavity and least attenuated by the filtering effect of the DBRs.

The sacrificial layer 104 may provide structural support to the lower cladding layer 108. In some cases, sacrificial layer 104 may provide a thermal path between the multiple thermally-controllable heaters and the substrate 102.

The gain section, corresponding to the first active region 118, and the SOA section, corresponding to the second active region 122, may be referred to as non-thermally-controllable sections since these sections are not thermally-controlled or tuned by a thermally-controllable heater (e.g., by on-chip heater sections). In contrast, the back DBR 114, the front DBR 116, and the phase control section 120 may be referred to as thermally-controllable sections since these sections are thermally-controlled or tuned by a thermally-controllable heater. It is noted that the gain section and the SOA section may be thermally controlled by other means. For instance, the gain section and the SOA section may be cooled by a separate mechanism, such as by mounting the entire chip on a thermoelectric cooler (TEC), to manage the temperature.

As indicated above, FIG. 1 is provided as an example. Other examples may differ from what is described with regard to FIG. 1. The number and arrangement of devices and components shown in FIG. 1 are provided as an example. In practice, there may be additional devices or components, fewer devices or components, different devices or components, or differently arranged devices or components than those shown in FIG. 1.

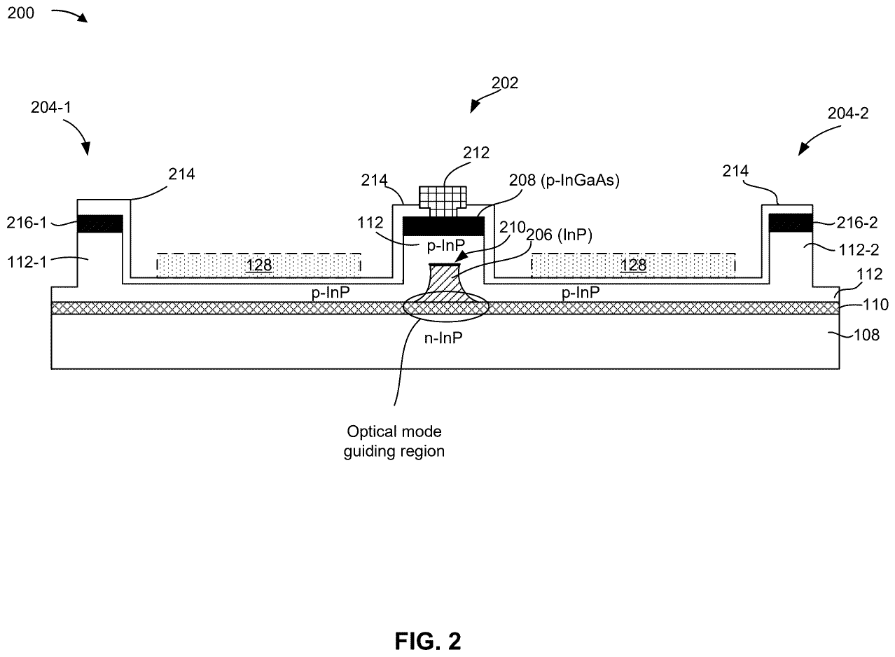

FIG. 2 shows a cross-section of a waveguide structure 200 according to one or more implementations. The waveguide structure 200 may be incorporated into to the waveguide structure 100 described in connection with FIG. 1. For example, the cross-section shown in FIG. 2 may be taken along a width-wise dimension of the waveguide structure 100, transverse to the output direction of output laser light (e.g. perpendicular to the propagation direction). The cross-section shown in FIG. 2 may be taken across a thermally-controllable section of the waveguide structure 100. For example, the cross-section shown in FIG. 2 may be taken across the back DBR 114, the front DBR 116, or the phase control section 120. Thus, the waveguide structure 200 may be part of a Vernier-tuned laser structure with narrow linewidth, widely-tunable semiconductor laser structures that are monolithically-integrated for coherent transmission at 800 Gbps and greater, with extended band tuning range (C++, L++).

The waveguide structure 200 includes the waveguide formed by the lower cladding layer 108, the waveguide core layer 110, and the upper cladding layer 112, as described above in connection with FIG. 1. The waveguide core layer 110 may include an optical mode guiding region in which light is guided for propagation. Thermally-controllable heaters 128 are arranged on the upper cladding layer 112. The thermally-controllable heaters 128 are configured to thermally tune the thermally-controllable section of the waveguide core layer 110.

The waveguide structure 200 includes a primary waveguide ridge 202 that extends outward from the upper cladding layer 112 in a vertical direction. Additionally, the waveguide structure 200 may include secondary waveguide ridges laterally displaced from the primary waveguide ridge 202. For example, the waveguide structure 200 may include a first secondary waveguide ridge 204-1 laterally displaced from the primary waveguide ridge 202 in a first lateral direction (e.g., on a left lateral side), and a second secondary waveguide ridge 204-2 laterally displaced from the primary waveguide ridge 202 in a second lateral direction opposite to the first lateral direction (e.g., on a right lateral side). One of the thermally-controllable heaters 128 is arranged laterally between the primary waveguide ridge 202 and the first secondary waveguide ridge 204-1, and the other one of the thermally-controllable heaters 128 is arranged laterally between the primary waveguide ridge 202 and the second secondary waveguide ridge 204-2.

The primary waveguide ridge 202 is formed by a spacer layer 206, the upper cladding layer 112, and a contact layer 208 arranged in a layer stack. The spacer layer 206 may be referred to as a doping setback layer or a not-intentionally-doped layer (some doping may unintentionally occur during processing). Thus, the spacer layer 206 may be undoped or may have some unintentional doping that occurs during processing. The spacer layer 206 may be arranged on the waveguide core layer 110 and may extend from the waveguide core layer 110 in the vertical direction to form a protrusion that forms a partial bottom portion of the primary waveguide ridge 202.

The primary waveguide ridge 202 is further formed by the upper cladding layer 112. Here, doped the upper cladding layer 112 laterally surrounds and extends over an upper surface of the spacer layer 206 to form peripheral portions and a middle portion of the primary waveguide ridge 202.

The contact layer 208 (e.g., a p-InGaAs layer) may be arranged, in the primary waveguide ridge 202, on the upper cladding layer 112 to form an upper portion of the primary waveguide ridge 202.

The lower cladding layer 108, the upper cladding layer 112, and the spacer layer 206 may be indium phosphide (InP) layers, the waveguide core layer 110 may be an InGaAsP layer, and the contact layer 208 may be an indium gallium arsenide (InGaAs) layer. In addition, the lower cladding layer 108 may have a first conductivity type (e.g., n-type), and the upper cladding layer 112 and the contact layer 208 may have a second conductivity type (e.g., p-type). Moreover, in some implementations, the primary waveguide ridge 202 may include a diffusion blocking layer 210 arranged on the upper surface of the spacer layer 206, between the spacer layer 206 and the upper cladding layer 112 within the primary waveguide ridge 202. The diffusion blocking layer 210 may be a silicon-doped diffusion blocking layer. In some examples, the diffusion blocking layer 210 may be an n-type diffusion blocking layer that is configured to block a diffusion of dopants of the second conductivity type (e.g., p-type).

The waveguide structure 200 may further include a ground ohmic contact 212 arranged on the primary waveguide ridge 202, the ground ohmic contact 212 being in contact with the contact layer 208. Thus, the primary waveguide ridge 202 may be referred to as a ridge-top-ground structure. The peripheral portions and the middle portion of the primary waveguide ridge 202, formed by the upper cladding layer 112, are configured to facilitate electrical grounding while not contributing to excessive optical loss. For example, the p-InP sections within the primary waveguide ridge 202, formed by the upper cladding layer 112, add p-doping to a periphery of the primary waveguide ridge 202 where an overlap of the p-doping with the optical mode is least destructive, but where the p-doping can contribute to maintaining a constant electrical potential.

The waveguide structure 200 may further include a dielectric layer 214 arranged on the upper cladding layer 112, on the primary waveguide ridge 202, on the first secondary waveguide ridge 204-1, and on the second secondary waveguide ridge 204-2. The dielectric layer 214 is arranged between the upper cladding layer 112 and the thermally-controllable heaters 128. Additionally, the dielectric layer 214 conforms to a shape of the primary waveguide ridge 202, the first secondary waveguide ridge 204-1, and the second secondary waveguide ridge 204-2. The dielectric layer 214 provides electrical isolation to the waveguide.

The first secondary waveguide ridge 204-1 may be formed by a first protrusion 112-1 of the upper cladding layer 112 and a first grounding contact layer 216-1 (e.g., a p-InGaAs layer) arranged on the first protrusion 112-1 of the upper cladding layer 112. The second secondary waveguide ridge 204-2 may be formed by a second protrusion 112-2 of the upper cladding layer 112 and a second grounding contact layer 216-2 (e.g., a p-InGaAs layer) arranged on the second protrusion 112-2 of the upper cladding layer 112.

The primary waveguide ridge 202 forms a stripe along a top of the upper cladding layer 112 in the length-wise dimension of the waveguide structure 200. Likewise, the first secondary ridge 204-1 and the second secondary ridge 204-2 form stripes along a top of the upper cladding layer 112 in the length-wise dimension of the waveguide structure 200. The first secondary ridge 204-1 and the second secondary ridge 204-2 extend parallel to the primary waveguide ridge 202 in the length-wise dimension of the waveguide structure 200. The thermally-controllable heaters 128 extend parallel to the primary waveguide ridge 202 along the top of the upper cladding layer 112 in the length-wise dimension of the waveguide structure 200.

In addition, the waveguide of the waveguide structure 200 includes one or more non-thermally-controllable sections, where each non-thermally-controllable section includes an active region. The spacer layer 206 is provided at each thermally-controllable section of the waveguide, but is not present at the non-thermally-controllable sections of the waveguide. In other words, length-wise sections of the primary waveguide ridge 202 that are arranged within gain sections of the waveguide structure 200 do not include the spacer layer 206, whereas length-wise sections of the primary waveguide ridge 202 that are arranged within thermally-controllable sections of the waveguide structure 200do include the spacer layer 206. Here, a “non-thermally-controllable section” refers to a section that is not thermally-controlled or tuned by a thermally-controllable heater, and a “thermally-controllable section” refers to a section that is thermally-controlled or tuned by a thermally-controllable heater. It is noted that a non-thermally-controllable section may be thermally controlled by other means. For instance, the gain section and the SOA section may be cooled by a separate mechanism, such as by mounting the entire chip on a thermoelectric cooler (TEC), to manage the temperature.

As indicated above, FIG. 2 is provided as an example. Other examples may differ from what is described with regard to FIG. 2.

FIG. 3 shows a cross-section of a waveguide structure 300 according to one or more implementations. The waveguide structure 300 may be incorporated into the waveguide structure 100 described in connection with FIG. 1. For example, the cross-section shown in FIG. 3 may be taken along a width-wise dimension of the waveguide structure 100, transverse to the output direction of output laser light (e.g. perpendicular to the propagation direction). The cross-section shown in FIG. 3 may be taken across a thermally-controllable section of the waveguide structure 100. For example, the cross-section shown in FIG. 3 may be taken across the back DBR 114, the front DBR 116, or the phase control section 120. Thus, the waveguide structure 300 may be part of a Vernier-tuned laser structure with narrow linewidth, widely-tunable semiconductor laser structures that are monolithically-integrated for coherent transmission at 800 Gbps and greater, with extended band tuning range (C++, L++).

The waveguide structure 300 includes the waveguide formed by the lower cladding layer 108, the waveguide core layer 110, and the upper cladding layer 112, as described above in connection with FIG. 1. The waveguide core layer 110 may include an optical mode guiding region in which light is guided for propagation. Thermally-controllable heaters 128 are arranged on the upper cladding layer 112. The thermally-controllable heaters 128 are configured to thermally tune the thermally-controllable section of the waveguide core layer 110.

The waveguide structure 300 includes a primary waveguide ridge 302 that extends outward from the waveguide core layer 110 in a vertical direction. Additionally, the waveguide structure 300 includes secondary ridges laterally displaced from the primary waveguide ridge 302. For example, the waveguide structure 300 may include a first secondary ridge 304-1 laterally displaced from the primary waveguide ridge 302 in a first lateral direction (e.g., on a left lateral side), and a second secondary ridge 304-2 laterally displaced from the primary waveguide ridge 302 in a second lateral direction opposite to the first lateral direction (e.g., on a right lateral side). One of the thermally-controllable heaters 128 is arranged laterally between the primary waveguide ridge 302 and the first secondary ridge 304-1, and the other one of the thermally-controllable heaters 128 is arranged laterally between the primary waveguide ridge 302 and the second secondary ridge 304-2.

The primary waveguide ridge 302 may be formed by a spacer layer 306 (e.g., an InP layer) and a doped layer 308 (e.g., a p-InP layer) arranged on the spacer layer 306. The spacer layer 306 may be referred to as a doping setback layer or a not-intentionally-doped layer (some doping may unintentionally occur during processing). Thus, the spacer layer 206 may be undoped or may have some unintentional doping that occurs during processing. The spacer layer 306 may arranged on the waveguide core layer 110 and may extend from the waveguide core layer 110 in the vertical direction to form a protrusion that forms a bottom portion of the primary waveguide ridge 302. The doped layer 308 may be arranged on the spacer layer 306 to form an upper portion of the primary waveguide ridge 302. The upper cladding layer 112 extends bilaterally from the spacer layer 306.

In addition, the primary waveguide ridge 302 may include a diffusion blocking layer 310 arranged between the spacer layer 306 and the doped layer 308. The diffusion blocking layer 310 may be a silicon-doped diffusion blocking layer. In some examples, the diffusion blocking layer 310 may be an n-type diffusion blocking layer that is configured to block a diffusion of dopants of the second conductivity type (e.g., p-type). The spacer layer 306 and the doped layer 308 extend laterally across an entire lateral dimension of the primary waveguide ridge 302. If the diffusion blocking layer 310 is present, the diffusion blocking layer 310 may also extend laterally across an entire lateral dimension of the primary waveguide ridge 302. The lower cladding layer 108, the upper cladding layer 112, the spacer layer 306, and the doped layer 308 may be indium phosphide (InP) layers, with the lower cladding layer having the first conductivity type (e.g., n-type), and the upper cladding layer 112 and the doped layer 308 having the second conductivity type (e.g., p-type).

The first secondary ridge 304-1 is formed by a first protrusion 112-1 of the upper cladding layer 112 and a first contact layer 312-1 (e.g., a p-InGaAs layer) arranged on the first protrusion 112-1 of the upper cladding layer 112. The second secondary ridge 304-2 is formed by a second protrusion 112-2 of the upper cladding layer 112 and a second contact layer 312-2 (e.g., a p-InGaAs layer) arranged on the second protrusion 112-2 of the upper cladding layer 112. Thus, the first contact layer and the second contact layer may be indium gallium arsenide (InGaAs) layers and may have the second conductivity type.

The waveguide structure 300 may further include a first ground ohmic contact 314-1 arranged on the first secondary waveguide ridge 304-1, the first ground ohmic contact 314-1 being in contact with the first contact layer 312-1. Additionally, the waveguide structure 300 may further include a second ground ohmic contact 314-2 arranged on the second secondary waveguide ridge 304-2, the second ground ohmic contact 314-2 being in contact with the second contact layer 312-2. Thus, the first secondary waveguide ridge 304-1 and the second secondary waveguide ridge 304-2 may be referred to as ridge-top-ground structures. Thus, optically-lossy InGaAs and metal ohmic contact layers are removed from the primary waveguide ridge 302 and moved to the secondary ridges 304-1 and 304-2 that have a lower ability to absorb light scattered from a grating, and thereby minimize optical self-heating. In addition, a lateral electrical conduction path between the first secondary ridge 304-1 and the primary waveguide ridge 302 and a lateral electrical conduction path between the second secondary waveguide ridge 304-2 and the primary waveguide ridge 302 provide carrier fluctuation control.

The waveguide structure 300 may further include a dielectric layer 316 arranged on the upper cladding layer 112, on the primary waveguide ridge 302, on the first secondary waveguide ridge 304-1, and on the second secondary waveguide ridge 304-2. The dielectric layer 316 is arranged between the upper cladding layer 112 and the thermally-controllable heaters 128. Additionally, the dielectric layer 316 conforms to a shape of the primary waveguide ridge 302, the first secondary ridge 304-1, and the second secondary ridge 304-2. The dielectric layer 316 provides electrical isolation to the waveguide.

As indicated above, FIG. 3 is provided as an example. Other examples may differ from what is described with regard to FIG. 3.

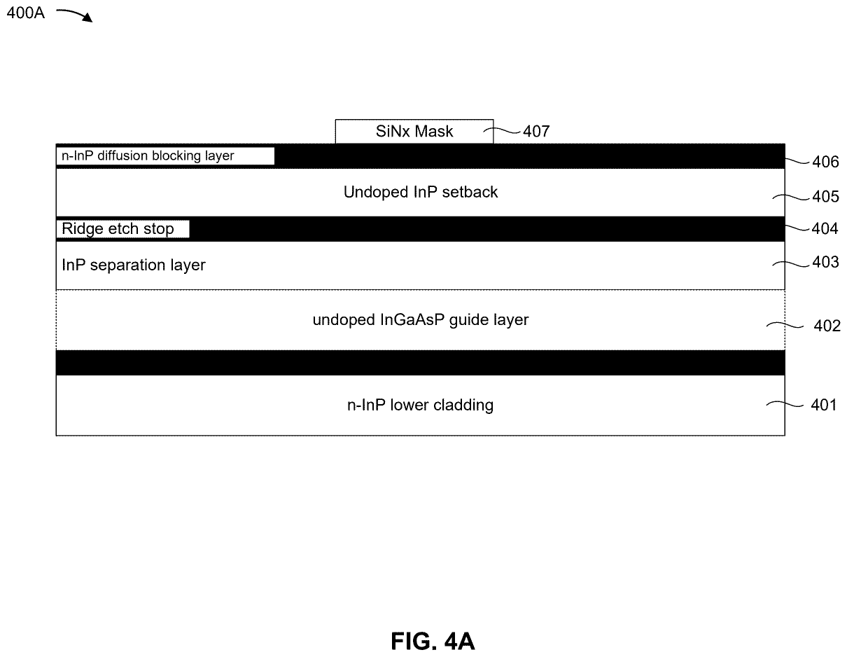

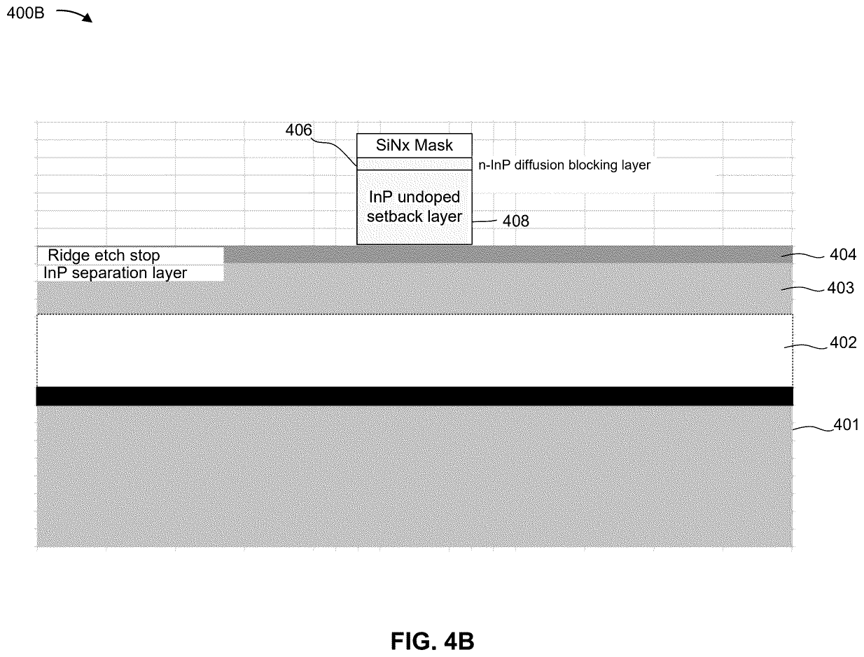

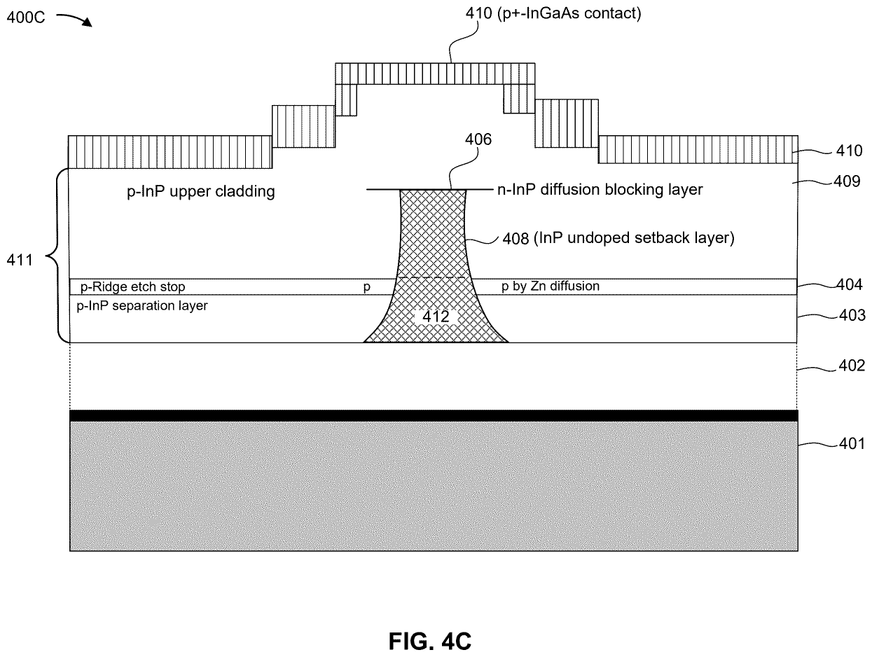

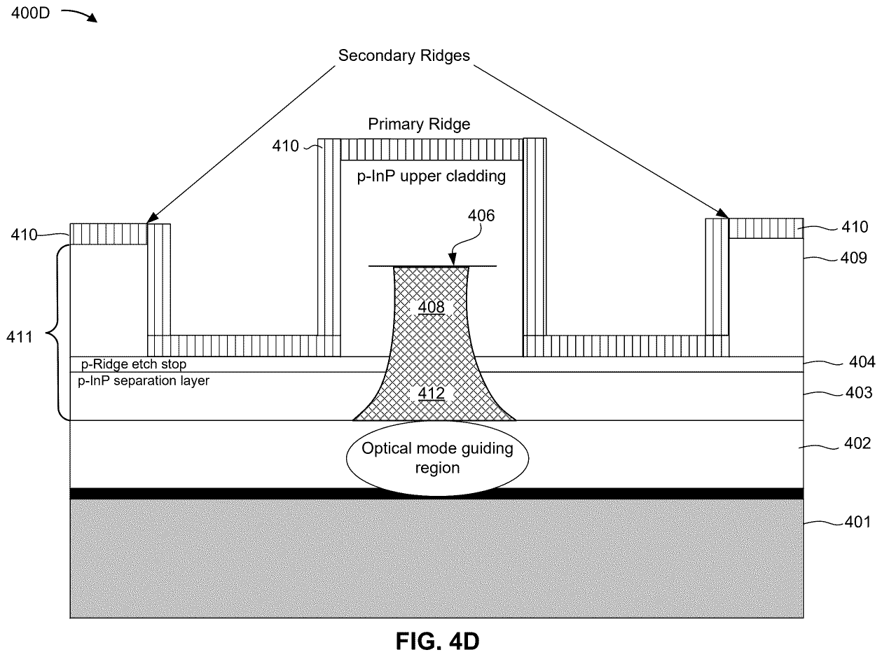

FIGS. 4A-4D show a fabrication process to produce a RTG waveguide structure according to one or more implementations. For example, the fabrication process may be used to manufacture the waveguide structure 200 described in connection with FIG. 2.

FIG. 4A shows a process stage 400A of the fabrication process according to one or more implementations. The process stage 400A may include forming (e.g., via an epilayer growth) an initial layer stack that includes an n-InP lower cladding layer 401, an undoped InGaAsP waveguide core layer 402, an undoped separation layer 403, an undoped InGaAsP ridge etch stop layer 404, and an undoped InP setback layer 405. In some examples, an n-InP diffusion blocking layer may be formed on the undoped InP setback layer 405. Additionally, a dielectric mask 407 may be formed on the undoped InP setback layer 405 (or on the n-InP diffusion blocking layer 406, if present) at a location corresponding to a primary waveguide ridge to be formed. The undoped layers referenced above may be not-intentionally-doped layers.

FIG. 4B shows a process stage 400B of the fabrication process according to one or more implementations. The process stage 400B may include etching the undoped InP setback layer 405 to form an undoped mesa structure 408 (or a not-intentionally-doped mesa structure), which includes a remaining portion of the undoped InP setback layer 405. A remaining portion of the n-InP diffusion blocking layer 406, if present, may be provided on top of the undoped mesa structure 408. The undoped mesa structure 408 may form a base of the primary waveguide ridge.

FIG. 4C shows a process stage 400C of the fabrication process according to one or more implementations. The process stage 400C may include forming an overgrowth of a p-doped InP upper cladding layer 409 and a p+InGaAs contact layer 410 on the InGaAsP ridge etch stop layer 404. The overgrowth of the p-doped InP upper cladding layer 409, along with the undoped separation layer 403 and the undoped InGaAsP ridge etch stop layer 404, may form an upper cladding layer 411 that has a doping of the second conductivity type (e.g., p-type). For example, forming the upper cladding layer 411 may include doping the undoped separation layer 403 and the undoped InGaAsP ridge etch stop layer 404 with dopants of the second conductivity type to form a p-InP separation layer and p-doped ridge etch stop layer, where a section 412 of the undoped separation layer 403 and the undoped ridge etch stop layer 404 underneath the undoped mesa structure 408 remains undoped. The section 412 of the undoped separation layer 403 and the undoped ridge etch stop layer 404 and the undoped mesa structure 408 form an undoped spacer layer (or a not-intentionally-doped layer spacer layer) of the primary waveguide ridge.

Forming the upper cladding layer 411 may also include growing the overgrowth of a p-doped InP upper cladding layer 409 as additional doped layer (e.g., p-InP) over the separation layer 403 (e.g., over the ridge etch stop layer 404) and over the undoped mesa structure 408 such that the additional doped layer covers peripheral sides and an upper surface of the undoped mesa structure 408. Once the additional doped layer is formed, the process stage 400C may include forming the contact layer 410 on the p-doped InP upper cladding layer (e.g., on the additional doped layer), the contact layer 410 having a doping of the second conductivity type.

FIG. 4D shows a process stage 400D of the fabrication process according to one or more implementations. The process stage 400D may include etching the contact layer 410 and the p-doped InP upper cladding layer (e.g., the additional doped layer) to form a primary waveguide ridge and a plurality of secondary waveguide ridges (e.g., two secondary waveguide ridges). The primary waveguide ridge includes the undoped mesa structure 408, a portion of the p-doped InP upper cladding layer 409, and a portion of the contact layer 410. The portion of the p-doped InP upper cladding layer 409 covers the peripheral sides and the upper surface of the undoped mesa structure 408.

In addition, a ground ohmic contact (e.g., ground ohmic contact 212) may be deposited or otherwise formed on the portion of the contact layer 410 of the primary waveguide ridge. For example, after the primary waveguide ridge and the secondary waveguide ridges are formed, the fabrication process may include passivating dielectric deposition, contact window opening, and P-ohmic metallization.

As indicated above, FIGS. 4A-4D are provided as examples. Other examples may differ from what is described with regard to FIGS. 4A-4D. In some cases, the fabrication process described in reference to FIGS. 4A-4D may be modified to manufacture the waveguide structure 300 described in connection with FIG. 3.

The following provides an overview of some Aspects of the present disclosure:

Aspect 1: A waveguide structure, comprising: a substrate; a lower cladding layer arranged on the substrate; a waveguide core layer arranged on the lower cladding layer, the waveguide core layer configured to generate, guide, and amplify laser light; a back DBR arranged in the waveguide core layer; a front DBR arranged in the waveguide core layer, wherein the back DBR and the front DBR define a laser cavity of the waveguide core layer; one or more active regions arranged in the waveguide core layer for light generation and amplification; an upper cladding layer arranged on the waveguide core layer, wherein the lower cladding layer, the waveguide core layer, and the upper cladding layer form a waveguide; a thermally-controllable heater arranged on the upper cladding layer, the thermally-controllable heater configured to thermally tune a thermally-controllable section of the waveguide core layer; a primary waveguide ridge that extends outward from the upper cladding layer in a vertical direction, wherein the primary waveguide ridge is formed by a not-intentionally-doped spacer layer, the upper cladding layer, and a contact layer arranged in a layer stack, wherein the undoped spacer layer is arranged on the waveguide core layer and extends from the waveguide core layer in the vertical direction to form a protrusion that forms a partial bottom portion of the primary waveguide ridge, wherein the upper cladding layer laterally surrounds and extends over an upper surface of the undoped spacer layer to form peripheral portions and a middle portion of the primary waveguide ridge, and the contact layer is arranged on the upper cladding layer to form an upper portion of the primary waveguide ridge; and a ground ohmic contact arranged on the primary waveguide ridge, the ground ohmic contact being in contact with the contact layer.

Aspect 2: The waveguide structure of Aspect 1, wherein the waveguide includes a non-thermally-controllable section that includes an active region of the one or more active regions, and wherein the undoped spacer layer is provided over the thermally-controllable section of the waveguide and is not present over the non-thermally-controllable section of the waveguide.

Aspect 3: The waveguide structure of any of Aspects 1-2, wherein the peripheral portions and the middle portion of the primary waveguide ridge, formed by the upper cladding layer, are configured to facilitate electrical grounding while not contributing to excessive optical loss.

Aspect 4: The waveguide structure of any of Aspects 1-3, wherein the lower cladding layer has a first conductivity type, wherein the upper cladding layer and the contact layer have a second conductivity type.

Aspect 5: The waveguide structure of Aspect 4, wherein the primary waveguide ridge includes a diffusion blocking layer arranged on the upper surface of the undoped spacer layer, between the undoped spacer layer and the upper cladding layer, wherein the diffusion blocking layer is configured to block a diffusion of dopants of the second conductivity type.

Aspect 6: The waveguide structure of Aspect 4, wherein the first conductivity type is n-type, and wherein the second conductivity type is p-type.

Aspect 7: The waveguide structure of Aspect 4, wherein the lower cladding layer, the upper cladding layer, and the undoped spacer layer are made of indium phosphide (InP), and wherein the contact layer is made of indium gallium arsenide (InGaAs).

Aspect 8: The waveguide structure of any of Aspects 1-7, further comprising: a first secondary waveguide ridge laterally displaced from the primary waveguide ridge in a first lateral direction; and a second secondary waveguide ridge laterally displaced from the primary waveguide ridge in a second lateral direction opposite to the first lateral direction, wherein the first secondary waveguide ridge is formed by a first protrusion of the upper cladding layer and a first grounding contact layer arranged on the first protrusion of the upper cladding layer, and wherein the second secondary waveguide ridge is formed by a second protrusion of the upper cladding layer and a second grounding contact layer arranged on the second protrusion of the upper cladding layer.

Aspect 9: The waveguide structure of Aspect 8, wherein the thermally-controllable heater is arranged laterally between the primary waveguide ridge and the first secondary waveguide ridge, or laterally between the primary waveguide ridge and the second secondary waveguide ridge.

Aspect 10: The waveguide structure of any of Aspects 1-9, further comprising: a dielectric layer arranged on the upper cladding layer and on the primary waveguide ridge, wherein the dielectric layer is arranged between the upper cladding layer and the thermally-controllable heater, and wherein the dielectric layer conforms to a shape of the primary waveguide ridge.

Aspect 11: The waveguide structure of any of Aspects 1-10, further comprising: a sacrificial layer arranged between the substrate and the lower cladding layer, wherein a removed portion of the sacrificial layer defines one or more thermally insulating regions between the substrate and the lower cladding layer,

Aspect 12: The waveguide structure of any of Aspects 1-11, wherein the thermally-controllable heater is configured to thermally tune the back DBR, the front DBR, or a phase control section of the waveguide core layer.

Aspect 13: The waveguide structure of any of Aspects 1-12, wherein the primary waveguide ridge forms a stripe along a top of the upper cladding layer, and wherein the thermally-controllable heater extends parallel to the primary waveguide ridge along the top of the upper cladding layer.

Aspect 14: The waveguide structure of any of Aspects 1-13, wherein the primary waveguide ridge is a ridge-top-ground structure.

Aspect 15: The waveguide structure of any of Aspects 1-14, wherein front DBR and the back DBR form a wavelength selective filter such that the laser light is generated within a narrow band of wavelengths.

Aspect 16: A waveguide structure, comprising: a substrate; a lower cladding layer arranged on the substrate; a waveguide core layer arranged on the lower cladding layer, the waveguide core layer configured to generate, guide and amplify laser light; a back DBR arranged in the waveguide core layer; a front DBR arranged in the waveguide core layer, wherein the back DBR and the front DBR define a laser cavity of the waveguide core layer; one or more active regions arranged in the waveguide core layer for light generation and amplification; an upper cladding layer arranged on the waveguide core layer, wherein the lower cladding layer, the waveguide core layer, and the upper cladding layer form a waveguide; a thermally-controllable heater arranged on the upper cladding layer, the thermally-controllable heater configured to thermally tune a thermally-controllable section of the waveguide core layer; a primary waveguide ridge that extends outward from the waveguide core layer in a vertical direction, wherein the primary waveguide ridge is formed by a not-intentionally-doped spacer layer, and a doped layer arranged on the undoped spacer layer, wherein the undoped spacer layer is arranged on the waveguide core layer and extends from the waveguide core layer in the vertical direction to form a protrusion that forms a bottom portion of the primary waveguide ridge, and wherein the doped layer is arranged on the undoped spacer layer to form an upper portion of the primary waveguide ridge; a first secondary waveguide ridge laterally displaced from the primary waveguide ridge in a first lateral direction, wherein the first secondary waveguide ridge is formed by a first protrusion of the upper cladding layer and a first contact layer arranged on the first protrusion of the upper cladding layer; and a first ground ohmic contact arranged on the first secondary waveguide ridge, the first ground ohmic contact being in contact with the first contact layer.

Aspect 17: The waveguide structure of Aspect 16, wherein the upper cladding layer extends bilaterally from the undoped spacer layer.

Aspect 18: The waveguide structure of any of Aspects 16-17, wherein the undoped spacer layer and the doped layer extend laterally across an entire lateral dimension of the primary waveguide ridge.

Aspect 19: The waveguide structure of any of Aspects 16-18, further comprising: a second secondary waveguide ridge laterally displaced from the primary waveguide ridge in a second lateral direction opposite to the first lateral direction, wherein the second secondary waveguide ridge is formed by a second protrusion of the upper cladding layer and a second contact layer arranged on the second protrusion of the upper cladding layer; and a second ground ohmic contact arranged on the second secondary waveguide ridge, the second ground ohmic contact being in contact with the second contact layer.

Aspect 20: The waveguide structure of Aspect 19, wherein the lower cladding layer has a first conductivity type, wherein the upper cladding layer, the doped layer, the first contact layer, and the second contact layer have a second conductivity type.

Aspect 21: The waveguide structure of Aspect 20, wherein the primary waveguide ridge includes a diffusion blocking layer arranged between the undoped spacer layer and the doped layer, wherein the diffusion blocking layer is configured to block a diffusion of dopants of the second conductivity type.

Aspect 22: The waveguide structure of Aspect 20, wherein the first conductivity type is n-type, and wherein the second conductivity type is p-type.

Aspect 23: The waveguide structure of Aspect 20, wherein the lower cladding layer, the upper cladding layer, the undoped spacer layer, and the doped layer are made of indium phosphide (InP), and wherein the first contact layer and the second contact layer are made of indium gallium arsenide (InGaAs).

Aspect 24: The waveguide structure of any of Aspects 16-23, wherein a lateral conduction path between the first secondary waveguide ridge and the primary waveguide ridge provides carrier fluctuation control.

Aspect 25: A method of manufacturing a monolithically-integrated narrow-linewidth tunable semiconductor laser device, the method comprising: providing an initial layer stack, comprising: a lower cladding layer, the lower cladding layer having a doping of a first conductivity type, a waveguide core layer arranged on the lower cladding layer, a separation layer arranged on the waveguide core layer, the separation layer being undoped, and a not-intentionally-doped setback layer arranged on the separation layer; etching the undoped setback layer to form a not-intentionally-doped mesa structure; forming an upper cladding layer, the upper cladding layer having a doping of a second conductivity type, wherein forming the upper cladding layer comprises: doping the separation layer with dopants of the second conductivity type, where a section of the separation layer underneath the undoped mesa structure remains undoped; and growing an additional doped layer over the separation layer and over the undoped mesa structure such that the additional doped layer covers peripheral sides and an upper surface of the undoped mesa structure; forming a contact layer on the additional doped layer, the contact layer having a doping of a second conductivity type; etching the contact layer and the additional doped layer to form a primary waveguide ridge and a plurality of secondary waveguide ridges, wherein the primary waveguide ridge includes the undoped mesa structure, a portion of the additional doped layer, and a portion of the contact layer, and wherein the portion of the additional doped layer covers the peripheral sides and the upper surface of the undoped mesa structure; and forming a ground ohmic contact on the portion of the contact layer.

Aspect 26: A waveguide structure, comprising: a substrate; a lower cladding layer arranged on the substrate; a waveguide core layer; an upper cladding layer arranged on the waveguide core layer, wherein the lower cladding layer, the waveguide core layer, and the upper cladding layer form a waveguide; a thermally-controllable heater arranged on the upper cladding layer, the thermally-controllable heater configured to thermally tune a thermally-controllable section of the waveguide core layer; a primary waveguide ridge that extends outward from the upper cladding layer in a vertical direction, wherein the primary waveguide ridge is formed by a not-intentionally-doped spacer layer, the upper cladding layer, and a contact layer arranged in a layer stack, wherein the undoped spacer layer is arranged on the waveguide core layer and extends from the waveguide core layer in the vertical direction to form a protrusion that forms a partial bottom portion of the primary waveguide ridge, wherein the upper cladding layer laterally surrounds and extends over an upper surface of the undoped spacer layer to form peripheral portions and a middle portion of the primary waveguide ridge, and the contact layer is arranged on the upper cladding layer to form an upper portion of the primary waveguide ridge; and a ground ohmic contact arranged on the primary waveguide ridge, the ground ohmic contact being in contact with the contact layer.

Aspect 27: A system configured to perform one or more operations recited in one or more of Aspects 1-26.

Aspect 28: An apparatus comprising means for performing one or more operations recited in one or more of Aspects 1-26.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A waveguide structure, comprising:
a substrate;
a lower cladding layer arranged on the substrate;
a waveguide core layer arranged on the lower cladding layer, the waveguide core layer configured to generate, guide, and amplify laser light;
a back distributed Bragg reflector (DBR) arranged in the waveguide core layer;
a front DBR arranged in the waveguide core layer, wherein the back DBR and the front DBR define a laser cavity of the waveguide core layer;
one or more active regions arranged in the waveguide core layer for light generation and amplification;
an upper cladding layer arranged on the waveguide core layer, wherein the lower cladding layer, the waveguide core layer, and the upper cladding layer form a waveguide;
a thermally-controllable heater arranged on the upper cladding layer, the thermally-controllable heater configured to thermally tune a thermally-controllable section of the waveguide core layer;
a primary waveguide ridge that extends outward from the upper cladding layer in a vertical direction, wherein the primary waveguide ridge is formed by a not-intentionally-doped spacer layer, the upper cladding layer, and a contact layer arranged in a layer stack,
wherein the undoped spacer layer is arranged on the waveguide core layer and extends from the waveguide core layer in the vertical direction to form a protrusion that forms a partial bottom portion of the primary waveguide ridge,
wherein the upper cladding layer laterally surrounds and extends over an upper surface of the undoped spacer layer to form peripheral portions and a middle portion of the primary waveguide ridge, and
the contact layer is arranged on the upper cladding layer to form an upper portion of the primary waveguide ridge; and
a ground ohmic contact arranged on the primary waveguide ridge, the ground ohmic contact being in contact with the contact layer.

2. The waveguide structure of claim 1, wherein the waveguide includes a non-thermally-controllable section that includes an active region of the one or more active regions, and
wherein the undoped spacer layer is provided over the thermally-controllable section of the waveguide and is not present over the non-thermally-controllable section of the waveguide.

3. The waveguide structure of claim 1, wherein the peripheral portions and the middle portion of the primary waveguide ridge, formed by the upper cladding layer, are configured to facilitate electrical grounding while not contributing to excessive optical loss.

4. The waveguide structure of claim 1, wherein the lower cladding layer has a first conductivity type,
wherein the upper cladding layer and the contact layer have a second conductivity type.

5. The waveguide structure of claim 4, wherein the primary waveguide ridge includes a diffusion blocking layer arranged on the upper surface of the undoped spacer layer, between the undoped spacer layer and the upper cladding layer,
wherein the diffusion blocking layer is configured to block a diffusion of dopants of the second conductivity type.

6. The waveguide structure of claim 4, wherein the first conductivity type is n-type, and
wherein the second conductivity type is p-type.

7. The waveguide structure of claim 4, wherein the lower cladding layer, the upper cladding layer, and the undoped spacer layer are made of indium phosphide (InP), and
wherein the contact layer is made of indium gallium arsenide (InGaAs).

8. The waveguide structure of claim 1, further comprising:
a first secondary ridge laterally displaced from the primary waveguide ridge in a first lateral direction; and
a second secondary ridge laterally displaced from the primary waveguide ridge in a second lateral direction opposite to the first lateral direction,
wherein the first secondary ridge is formed by a first protrusion of the upper cladding layer and a first grounding contact layer arranged on the first protrusion of the upper cladding layer, and
wherein the second waveguide ridge is formed by a second protrusion of the upper cladding layer and a second grounding contact layer arranged on the second protrusion of the upper cladding layer.

9. The waveguide structure of claim 8, wherein the thermally-controllable heater is arranged laterally between the primary waveguide ridge and the first secondary ridge, or laterally between the primary waveguide ridge and the second secondary ridge.

10. The waveguide structure of claim 1, further comprising:
a dielectric layer arranged on the upper cladding layer and on the primary waveguide ridge,
wherein the dielectric layer is arranged between the upper cladding layer and the thermally-controllable heater, and
wherein the dielectric layer conforms to a shape of the primary waveguide ridge.

11. The waveguide structure of claim 1, further comprising:
a sacrificial layer arranged between the substrate and the lower cladding layer, wherein a removed portion of the sacrificial layer defines one or more thermally insulating regions between the substrate and the lower cladding layer.

12. The waveguide structure of claim 1, wherein the thermally-controllable heater is configured to thermally tune the back DBR, the front DBR, or a phase control section of the waveguide core layer.

13. The waveguide structure of claim 1, wherein the primary waveguide ridge forms a stripe along a top of the upper cladding layer, and
wherein the thermally-controllable heater extends parallel to the primary waveguide ridge along the top of the upper cladding layer.

14. The waveguide structure of claim 1, wherein the primary waveguide ridge is a ridge-top-ground structure.

15. The waveguide structure of claim 1, wherein front DBR and the back DBR form a wavelength selective filter such that the laser light is generated within a narrow band of wavelengths.

16. A waveguide structure, comprising:
a substrate;
a lower cladding layer arranged on the substrate;
a waveguide core layer arranged on the lower cladding layer, the waveguide core layer configured to generate, guide and amplify laser light;
a back distributed Bragg reflector (DBR) arranged in the waveguide core layer;
a front DBR arranged in the waveguide core layer, wherein the back DBR and the front DBR define a laser cavity of the waveguide core layer;
one or more active regions arranged in the waveguide core layer for light generation and amplification;
an upper cladding layer arranged on the waveguide core layer, wherein the lower cladding layer, the waveguide core layer, and the upper cladding layer form a waveguide;
a thermally-controllable heater arranged on the upper cladding layer, the thermally-controllable heater configured to thermally tune a thermally-controllable section of the waveguide core layer;
a primary waveguide ridge that extends outward from the waveguide core layer in a vertical direction, wherein the primary waveguide ridge is formed by a not-intentionally-doped spacer layer, and a doped layer arranged on the undoped spacer layer,
wherein the undoped spacer layer is arranged on the waveguide core layer and extends from the waveguide core layer in the vertical direction to form a protrusion that forms a bottom portion of the primary waveguide ridge, and
wherein the doped layer is arranged on the undoped spacer layer to form an upper portion of the primary waveguide ridge;
a first secondary ridge laterally displaced from the primary waveguide ridge in a first lateral direction,
wherein the first secondary ridge is formed by a first protrusion of the upper cladding layer and a first contact layer arranged on the first protrusion of the upper cladding layer; and
a first ground ohmic contact arranged on the first waveguide ridge, the first ground ohmic contact being in contact with the first contact layer.

17. The waveguide structure of claim 16, wherein the upper cladding layer extends bilaterally from the undoped spacer layer.

18. The waveguide structure of claim 16, wherein the undoped spacer layer and the doped layer extend laterally across an entire lateral dimension of the primary waveguide ridge.

19. The waveguide structure of claim 16, further comprising:
a second secondary ridge laterally displaced from the primary waveguide ridge in a second lateral direction opposite to the first lateral direction,
wherein the second secondary ridge is formed by a second protrusion of the upper cladding layer and a second contact layer arranged on the second protrusion of the upper cladding layer; and
a second ground ohmic contact arranged on the second secondary ridge, the second ground ohmic contact being in contact with the second contact layer.

20. The waveguide structure of claim 19, wherein the lower cladding layer has a first conductivity type,
wherein the upper cladding layer, the doped layer, the first contact layer, and the second contact layer have a second conductivity type.

21. The waveguide structure of claim 20, wherein the primary waveguide ridge includes a diffusion blocking layer arranged between the undoped spacer layer and the doped layer,
wherein the diffusion blocking layer is configured to block a diffusion of dopants of the second conductivity type.

22. The waveguide structure of claim 20, wherein the first conductivity type is n-type, and
wherein the second conductivity type is p-type.

23. The waveguide structure of claim 20, wherein the lower cladding layer, the upper cladding layer, the undoped spacer layer, and the doped layer are made of indium phosphide (InP), and
wherein the first contact layer and the second contact layer are made of indium gallium arsenide (InGaAs).

24. The waveguide structure of claim 16, wherein a lateral conduction path between the first secondary waveguide ridge and the primary waveguide ridge provides carrier fluctuation control.

25. A method of manufacturing a monolithically-integrated narrow-linewidth tunable semiconductor laser device, the method comprising:
providing an initial layer stack, comprising:
a lower cladding layer, the lower cladding layer having a doping of a first conductivity type,
a waveguide core layer arranged on the lower cladding layer,
a separation layer arranged on the waveguide core layer, the separation layer being undoped, and
a not-intentionally-doped setback layer arranged on the separation layer;
etching the undoped setback layer to form a not-intentionally-doped mesa structure;
forming an upper cladding layer, the upper cladding layer having a doping of a second conductivity type, wherein forming the upper cladding layer comprises:
doping the separation layer with dopants of the second conductivity type, where a section of the separation layer underneath the undoped mesa structure remains undoped; and
growing an additional doped layer over the separation layer and over the undoped mesa structure such that the additional doped layer covers peripheral sides and an upper surface of the undoped mesa structure;
forming a contact layer on the additional doped layer, the contact layer having a doping of a second conductivity type;
etching the contact layer and the additional doped layer to form a primary waveguide ridge and a plurality of secondary waveguide ridges,
wherein the primary waveguide ridge includes the undoped mesa structure, a portion of the additional doped layer, and a portion of the contact layer, and
wherein the portion of the additional doped layer covers the peripheral sides and the upper surface of the undoped mesa structure; and
forming a ground ohmic contact on the portion of the contact layer.

26. A waveguide structure, comprising:
a substrate;
a lower cladding layer arranged on the substrate;
a waveguide core layer;
an upper cladding layer arranged on the waveguide core layer, wherein the lower cladding layer, the waveguide core layer, and the upper cladding layer form a waveguide;
a thermally-controllable heater arranged on the upper cladding layer, the thermally-controllable heater configured to thermally tune a thermally-controllable section of the waveguide core layer;
a primary waveguide ridge that extends outward from the upper cladding layer in a vertical direction, wherein the primary waveguide ridge is formed by a not-intentionally-doped spacer layer, the upper cladding layer, and a contact layer arranged in a layer stack,
wherein the undoped spacer layer is arranged on the waveguide core layer and extends from the waveguide core layer in the vertical direction to form a protrusion that forms a partial bottom portion of the primary waveguide ridge,
wherein the upper cladding layer laterally surrounds and extends over an upper surface of the undoped spacer layer to form peripheral portions and a middle portion of the primary waveguide ridge, and
the contact layer is arranged on the upper cladding layer to form an upper portion of the primary waveguide ridge; and
a ground ohmic contact arranged on the primary waveguide ridge, the ground ohmic contact being in contact with the contact layer.
